(19) United States
(12) Patent Application Publication
(10) Pub. No.: US 2012/0014183 A1
(43) Pub. Date: Jan. 19, 2012

(54) 3 TRANSISTOR (N/P/N) NON-VOLATILE MEMORY CELL WITHOUT PROGRAM DISTURB

(76) Inventors: Pavel Poplevine, Burlingame, CA (US); Ernes Ho, Campbell, CA (US); Umer Khan, Santa Clara, CA (US); Andrew J. Franklin, Santa Clara, CA (US)

(21) Appl. No.: 12/837,835

(22) Filed: Jul. 16, 2010

(51) Int. Cl. G11C 16/04

(52) U.S. Cl. 365/185.19; 365/185.18; 365/185.02

(57) ABSTRACT

A non-volatile memory (NVM) cell structure comprises an NMOS control transistor having source, drain and bulk region electrodes that are commonly-connected to receive a control voltage and a gate electrode that is connected to a data storage node; a PMOS erase transistor having source, drain and bulk region electrodes that are commonly-connected to receive an erase voltage and a gate electrode that is connected to the data storage node; and an NMOS data transistor having source, drain and bulk region electrodes and a gate electrode connected to the data storage node.

### TECHNICAL FIELD

The disclosed embodiments relate to integrated circuit memory devices and, in particular, to a 3 transistor non-volatile memory (NVM) cell without program disturb and with an N/P/N structure to accommodate very small area.

### BACKGROUND OF THE INVENTION

U.S. Pat. No. 7,164,606 B1, which issued on Jan. 16, 2007, to Poplevine et al., discloses an all PMOS 4-transistor non-volatile memory (NVM) cell that utilizes reverse Fowler-Nordheim tunneling for programming. U.S. Pat. No. 7,164,606 is hereby incorporated by reference herein in its entirety to provide background information regarding the present invention.

Referring to FIG. 1, as disclosed in U.S. Pat. No. 7,164,606, in accordance with the method of programming an NVM array that includes all-PMOS 4-transistor NVM cells having commonly-connected floating gates, for each cell 100 in the array that is to be programmed, all of the electrodes of the cell are grounded. Then, an inhibiting voltage V_{N} is applied to the bulk-connected source region Vᵣ of the cell's read transistor Pᵣ, to the commonly-connected drain, bulk and source regions Vₑ of the cell's erase transistor Pₑ, and to the drain region Dᵣ of the read transistor Pᵣ. The source region Vₚ and the drain region Dₚ of the cell's programming transistor P_{w} are grounded. The bulk V₁W of the programming transistor P_{w} is optional; it can be grounded or it can remain at the inhibiting voltage V_{N}. For all cells in the NVM array that are not selected for programming, the inhibiting voltage V_{N} is applied to the Vᵣ, Vₑ and Dᵣ electrodes and is also applied to the Vₚ, Dₚ and V_{nW} electrodes. The control gate voltage V_{c} of the cell's control transistor P_{c} is then swept from 0V to a maximum programming voltage V_{cmax} in a programming time T_{prog}. The control gate voltage V_{c} is then ramped down from the maximum programming voltage V_{cmax} to 0V. All electrodes of the cell and the inhibiting voltage V_{N} are then returned to ground.

During the above-described program sequence, the drain and source regions of the read transistor Pᵣ and the program transistor P_{w} of the non-programmed NVM cells are set to a fixed inhibiting voltage V_{N}, while the Vₑ electrode is set to voltage V_{N} and the V_{c} electrode is ramped up from 0V to V_{cmax}. As a result, negative charge still gets trapped to the floating gate of non-programmed NVM cells, even though the amount is less than the negative charge that gets trapped to the floating gate of programmed NVM cells. This sets the voltage level of the floating gate of non-programmed cells to about V_{N} above the voltage level of the floating gate of the programmed cells. This means that that the maximum possible voltage level difference between the floating gates of the programmed cells and the floating gates of the non-programmed cells is V_{N}. The non-programmed cells with this condition are referred to as disturbed cells.

Thus, while the all-PMOS 4-transistor NVM cell programming technique disclosed in the '606 patent provides advantages of both low current consumption, allowing the ability to simultaneously program a large number of cells without the need for high current power sources, and a simple program sequence, it would be highly desirable to have available an NVM cell that maintains the benefits of low programming current, but also avoids the disturbed cell condition.

### SUMMARY OF THE INVENTION

Embodiments provide a non-volatile memory (NVM) cell structure comprising: an NMOS control transistor having source, drain and bulk region electrodes that are commonly-connected to receive a control voltage and a gate electrode connected to a data storage node; a PMOS erase transistor having source, drain and bulk region electrodes that are commonly-connected to receive an erase voltage and a gate electrode connected to the data storage node; and an NMOS data transistor having source, drain and bulk region electrodes and a gate electrode connected to the data storage node.

Other embodiments provide a method of programming a non-volatile memory (NVM) cell, the NVM cell including an NMOS control transistor having source, drain and bulk region electrodes that are commonly-connected to receive a control voltage and a gate electrode that is connected to a data storage node; a PMOS erase transistor having source, drain and bulk region electrodes that are commonly-connected to receive an erase voltage and a gate electrode that is connected to the data storage node; and an NMOS data transistor having source, drain and bulk region electrodes and a gate electrode connected to the data storage node, the NVM cell programming method comprising: ramping up the control voltage and erase voltage electrodes from 0V to a predefined maximum control voltage V_{cmax} and a predefined maximum erase voltage Vₑₘₐₓ, respectively, while setting the source and drain voltages of the NMOS data transistor to 0V.

Other embodiments provide a method of programming a non-volatile memory (NVM) array that includes a plurality of rows of NVM cells, each NVM cell in the array including an NMOS control transistor having source, drain and bulk region electrodes that are commonly-connected to receive a control voltage and a gate electrode that is connected to a data storage node; a PMOS erase transistor having source, drain and bulk region electrodes that are commonly-connected to receive an erase voltage and a gate electrode connected to the data storage node; and an NMOS data transistor having source, drain and bulk region electrodes and a gate electrode connected to the data storage node, the NVM cell array programming method comprising: for those NVM cells in the array to be programmed, ramping up the control voltage and erase voltage electrodes from 0V to V_{cmax} and Vₑₘₐₓ, respectively, while setting the source and drain electrodes of the cell's NMOS data transistor to 0V.

The features and advantages of the various aspects of the present invention will be more fully understood and appreciated upon consideration of the following detailed description of the invention and the accompanying drawings, which set forth illustrative embodiments in which the concepts of the invention are utilized.

### BRIEF DESCRIPTION OF THE DRAWINGS

FIG. 1 is a schematic drawing illustrating an all-PMOS, 4-transistor NVM cell.

FIG. 2 is a schematic drawing illustrating an embodiment of a 3 transistor NVM cell.

FIG. 3 is a cross-section drawing illustrating the layout of the FIG. 1 all-PMOS, 4-transistor NVM cell.

FIG. 4 is a cross-section drawing illustrating an embodiment of a layout of the FIG. 2 3 transistor NVM cell.

FIG. 5 is a cross-section drawing illustrating an alternate embodiment of a layout of the FIG. 2 3 transistor NVM cell.

FIG. 6 is a block diagram illustrating an embodiment of an array 3 transistor NVM cells.

### DETAILED DESCRIPTION OF THE INVENTION

FIG. 2 shows an embodiment of a 3 transistor non-volatile memory (NVM) cell structure 200. The NVM cell structure 200 includes an NMOS control transistor N_{c} having source, drain and bulk region electrodes that are commonly-connected to receive a control voltage V_{c} and a gate electrode that is connected to the data storage node FG; a PMOS erase transistor Pₑ having source, drain and bulk region electrodes that are commonly-connected to receive an erase voltage Vₑ and a gate electrode connected to the data storage node FG; and an NMOS data transistor N_{d} having source, drain and bulk region electrodes and a gate electrode connected to the data storage node FG.

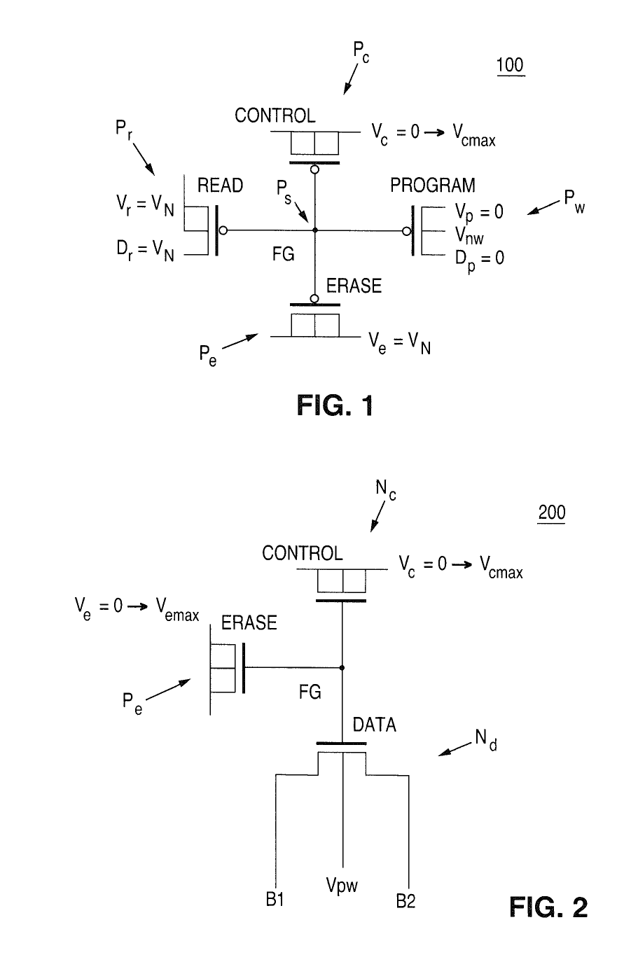

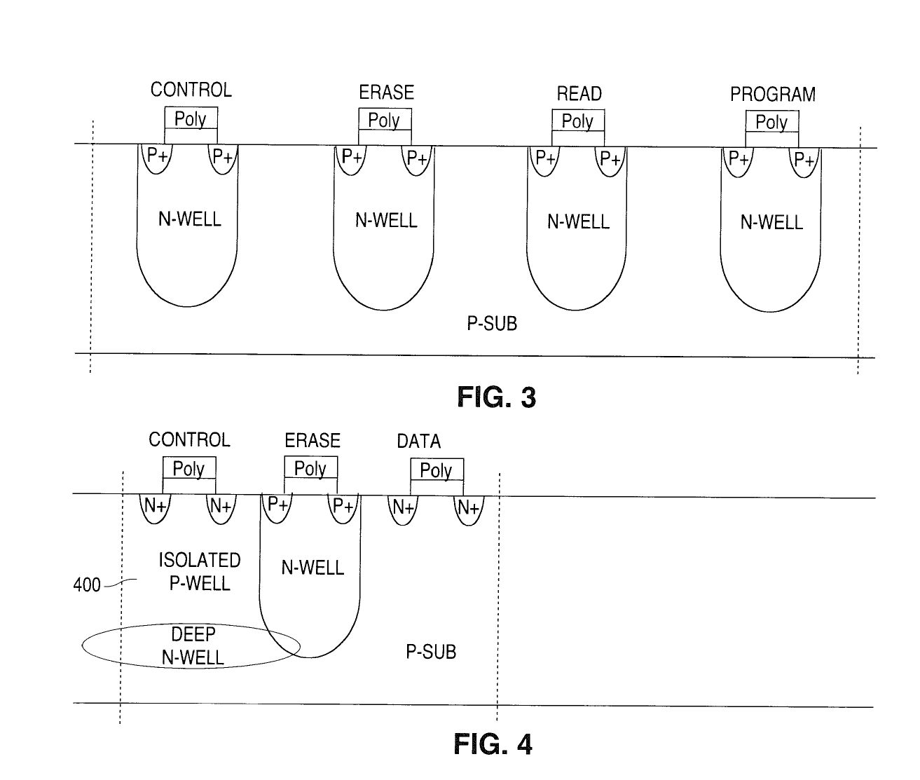

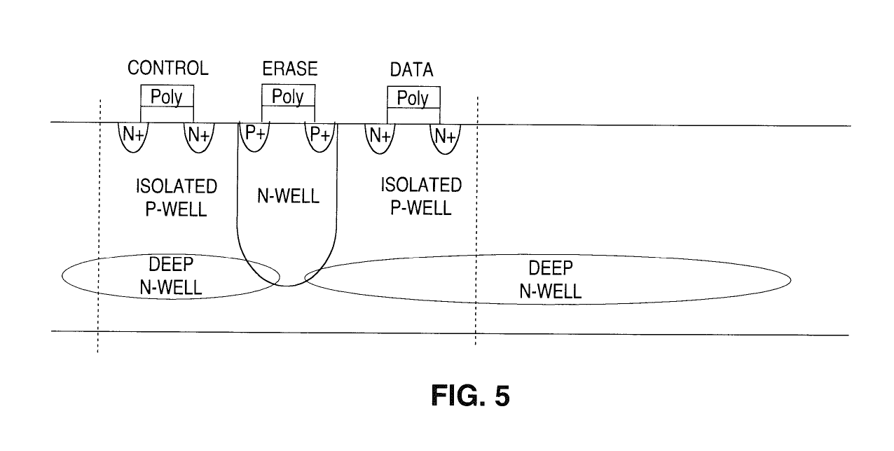

Thus, the FIG. 2 embodiment modifies the all PMOS 4-transistor NVM cell shown in FIG. 1 into a 3 transistor NVM cell 200. It changes the control transistor from PMOS to NMOS with isolated P-well (FIG. 4) and replaces the PMOS read transistor and the PMOS program transistor with one NMOS data transistor, thus providing an NMOS-PMOS-NMOS 3 transistor structure that has a more compact layout area compared to the all PMOS structure which, as shown in FIG. 3, often has large N-well spacing. The substrate region of the data transistor can either be a common P-substrate, as shown in FIG. 4, or an isolated P-well, as shown in FIG. 5. In each of FIGS. 3, 4 and 5, the region between the vertical dashed lines denotes one NVM cell.

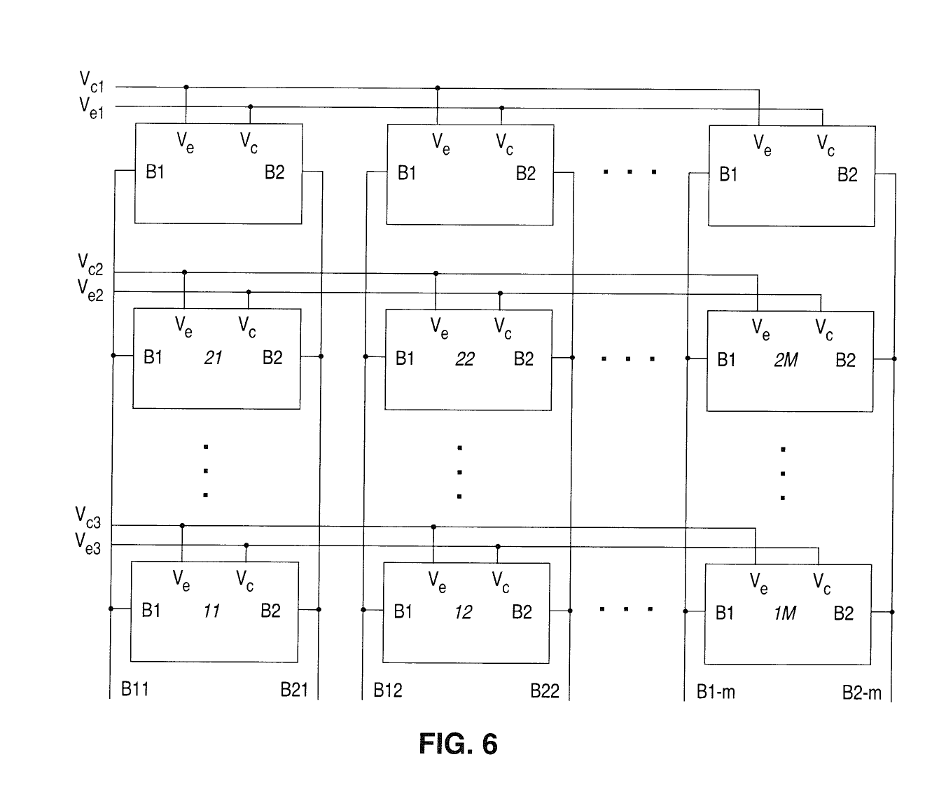

FIG. 6 shows an embodiment of an NVM cell array that incorporates 3 transistor NVM cells. In the FIG. 6 NVM cell array architecture, the rows of the array have a separated Vₑ electrodes and V_{c} electrodes to enable a row-by-row programming method.

During the programming sequence, as discussed further below (see Program Sequence), the Vₑ electrode and the V_{c} electrode of the selected row to be programmed are ramped from 0V to a predefined maximum erase voltage Vₑₘₐₓ and a predefined maximum control voltage V_{cmax}, respectively, while the B1 electrode or the B2 electrode or both are set to 0V. For the selected row not to be programmed (inhibit program), the Ve electrode and the V_{c} electrode are ramped up from 0V to the predefined maximum erase voltage Vₑₘₐₓ and the predefined maximum control voltage V_{cmax}, respectively, while the B1 electrode or the B2 electrode or both are set to an inhibiting voltage V_{N}. The Vₑ electrodes and V_{c} electrodes of non-selected rows remain at 0V. Thus, NVM cells in the non-selected rows will not be programmed or disturbed from the erase state, independent of the voltage value of the B1 electrode and the B2 electrode. This eliminates the need for passgate transistors on the B1 and B2 electrodes in the NVM array, thus keeping the size of the array small. The Vₑₘₐₓ and Vₑₘₐₓ voltage levels are chosen so that after an erase sequence (see Erase Condition below) and a programming sequence, the floating gate voltage of programmed cells is at V_{FG1}, and the floating gate voltage of non-programmed cells is at V_{FG2}, where V_{FG1} and V_{FG2} are lower than 0V, and V_{FG1} is smaller than V_{FG2} (for example, V_{FG1}=−4V and V_{FG2}=−1V).

During the read sequence, as discussed further below (see Read Condition), the Vₑ electrodes and V_{c} electrodes of non-selected rows are set to 0V, while the Vₑ electrode and V_{c} electrode of the selected row to be read are set to a predefined maximum read voltage Vᵣₘₐₓ, such that Vᵣₘₐₓ+V_{FG1} is lower than 0V and Vᵣₘₐₓ+V_{FG2} is higher than 0V (for example, Vᵣₘₐₓ=3V, so that Vᵣₘₐₓ+V_{FG1}==−1V and Vᵣₘₐₓ+V_{FG2}=+2V). Also, for all of the NVM cells in the array, the B1 electrodes are set to 0V and the B2 electrodes are set to a positive voltage such that the voltage difference between the B1 electrode and the B2 electrode is sufficient to be able to read while preventing disturb to programmed cells (for example, about 1V), or vice versa. Thus, in this read condition, all of the NVM cells from non-selected rows will give zero current output and non-programmed cells from the selected row to be read will give a non-zero current output.

The NVM cell and the NVM cell array retain the advantages of the Reverse Fowler-Nordheim Tunneling programming method described above with respect to U.S. Pat. No. 7,164,606.

Referring to FIG. 2 and to FIG. 6, a summary of the program, erase and read sequences for the FIG. 2 NVM cell 200 in an array row is as follows:

Program Sequence

1. All of the electrodes are set to 0V.
2. For the selected row to be programmed, set the B1 electrode to 0V and the B2 electrode to floating, or the B2 electrode to 0V and the B1 electrode to floating, or both electrodes to 0V, then ramp up the V_{c} electrode of the selected row from 0V to V_{cmax}, and the Vₑ electrode of the selected row from 0V to Vₑₘₐₓ, and hold it for the duration of a predefined program time T_{prog}. (Compared with the programming sequence for the all-PMOS 4 transistor NVM cell disclosed in U.S. Pat. No. 7,164,606, the Vₑ electrode is now ramped up along with the V_{c} electrode in order to prevent forward biasing the PN diode that is formed between the isolated P-well and the N-well). Then ramp down the V_{c} electrode of the selected row from V_{cmax} to 0V, and the Vₑ electrode of the selected row from Vₑₘₐₓ to 0V. The V_{pw} electrodes of the selected row are set to 0V.
3. For the selected row not to be programmed (inhibit program), set the B1 electrode to an inhibiting voltage V_{N} and the B2 electrode to floating, or the B2 electrode to the inhibiting voltage and the B1 electrode to floating, or both electrodes to the inhibiting voltage V_{N}, then ramp up the V_{c} electrode of the selected row from 0V to V_{cmax} and the Vₑ electrode of the selected row from 0V to Vₑₘₐₓ and hold these voltages for the duration of the predefined program time T_{prog} (Compared with the programming sequence for the all-PMOS 4 transistor NVM cell disclosed in U.S. Pat. No. 7,164,606, the Vₑ electrode is now ramped up along with the V_{c} electrode in order to prevent forward biasing the PN diode that is formed between the isolated P-well and the N-well, see FIGS. 4 and 5). Then ramp down the V_{c} electrode of the selected row from V_{cmax} to 0V, and the Vₑ electrode of the selected row from Vₑₘₐₓ to 0V. The V_{pw} electrodes of the selected row are set to 0V.
4. For non-selected rows, keep the V_{c} and Vₑ electrodes of these rows at 0V, the B1 electrode to 0V or the inhibiting voltage V_{N}, or the B2 electrode to 0V or the inhibiting voltage V_{N}.
5. Return all of the electrodes with the voltage V_{N} to 0V. After this, the programming sequence is completed, where programmed cells in the selected row will have been programmed and non-programmed cells in the selected row (inhibit program) will not have been programmed while non-programmed cells in non-selected rows will not have been programmed and in no-disturb condition.

Erase Condition

Ramp up the Vₑ electrode from 0V to the maximum erase voltage Vₑₘₐₓ, hold it for the duration of a predefine erase time Tₑᵣₐₛₑ, and ramp the Vₑ electrode back down from the maximum erase voltage Vₑₘₐₓ to 0V. All other cell electrodes are set to 0V.

Read Condition

Set the B1 electrode to 0V and the B2 electrode to a voltage difference of about 1V (e.g., sufficient enough voltage to be able to read the cell current while preventing disturb to the programmed cells), or vise versa. Set the V_{c} electrode and the Vₑ electrode of the selected row to be read to the maximum read voltage Vᵣₘₐₓ, and set the V_{c} electrodes and the Vₑ electrodes of the non-selected rows to 0V. All other electrodes are set to 0V.

Those skilled in the art will appreciate that the voltage levels utilized in the program, erase and read operations will depend upon the thickness of the gate oxide utilized in the NMOS and PMOS devices of the NVM cell 200. For example, for a gate oxide thickness of 60-80 Å, V_{N}˜=3.3V, V_{cmax}=Vₑₘₐₓ˜=10V, with T_{prog}=Tₑᵣₐₛₑ˜=20-50 milliseconds. For gate oxide thickness of 120 Å, V_{N}˜=5.0V, V_{cmax}=Vₑₘₐₓ˜=16V, with T_{prog}=Tₑᵣₐₛₑ˜=20-50 milliseconds.

It should be understood that the particular embodiments described above have been provided by way of example and that other modifications may occur to those skilled in the art without departing from the scope of the claimed subject matter as expressed in the appended claims and their equivalents.

What is claimed is:

1. A non-volatile memory (NVM) cell structure comprising:
an NMOS control transistor having source, drain and bulk region electrodes that are commonly-connected to receive a control voltage and a gate electrode connected to a data storage node;
a PMOS erase transistor having source, drain and bulk region electrodes that are commonly-connected to receive an erase voltage and a gate electrode connected to the data storage node; and
an NMOS data transistor having source, drain and bulk region electrodes and a gate electrode connected to the data storage node.

2. A method of programming a non-volatile memory (NVM) cell, the NVM cell including an NMOS control transistor having source, drain and bulk region electrodes that are commonly-connected to receive a control voltage and a gate electrode connected to the data storage node; a PMOS erase transistor having source, drain and bulk region electrodes that are commonly-connected to receive an erase voltage and a gate electrode connected to the data storage node; and an NMOS data transistor having source, drain and bulk region electrodes and a gate electrode connected to the data storage node, the NVM cell programming method comprising: ramping up the control voltage and erase voltage from 0V to a predefined maximum control voltage Vₑₘₐₓ and a predefined maximum erase voltage Vₑₘₐₓ, respectively, while setting the source and drain voltages of the NMOS data transistor to 0V.

3. The method of claim 2, and further comprising:
setting all electrodes to 0V;
setting the source electrode of the data transistor to 0V and the drain electrode of the data transistor to floating, or the drain electrode of the data transistor to 0V and the source electrode of the data transistor to floating, or both electrodes to 0V, setting the bulk region of the data transistor to 0V, then ramping up the control voltage from 0V to the predefined maximum control voltage V_{cmax} and the erase voltage from 0V to the predefined maximum erase voltage Vₑₘₐₓ and holding these voltages for a predefined program time T_{prog}, then ramping down the control voltage from V_{cmax} to 0V and the erase voltage from Vₑₘₐₓ to 0V.

4. The method of claim 3, wherein the predefined maximum control voltage Vₑₘₐₓ and the predefined maximum erase voltage Vₑₘₐₓ are both approximately 10V, and the predefined program time T_{prog} is approximately 20-50 milliseconds.

5. The method of claim 3, wherein the predefined maximum control voltage V_{cmax} and the predefined maximum erase voltage Vₑₘₐₓ are both approximately 16V, and the predefined program time T_{prog} is approximately 20-50 milliseconds.

6. A method of programming a non-volatile memory (NVM) cell array that includes a plurality of rows of NVM cells, each NVM cell in the array including an NMOS control transistor having source, drain and bulk region electrodes that are commonly-connected to receive a control voltage and a gate electrode connected to the data storage node; a PMOS erase transistor having source, drain and bulk region electrodes that are commonly-connected to receive an erase voltage and a gate electrode that is connected to the data storage node; and an NMOS data transistor having source, drain and bulk region electrodes and a gate electrode connected to the data storage node, the NVM cell array programming method comprising: for those NVM cells in the array to be programmed, ramping up the control voltage and erase voltage electrodes from 0V to a predefined maximum control voltage V_{cmax} and a predefined maximum erase voltage Vₑₘₐₓ, respectively, while setting the source and drain electrodes of the cell's NMOS data transistor to 0V.

7. The method of claim 6, and further comprising:
setting all electrodes to 0V;
for each NVM cell selected to be programmed in a selected array row, setting the source electrode of the data transistor to 0V and the drain electrode of the data transistor to floating, or setting the drain electrode of the data transistor to 0V and the source electrode of the data transistor to floating, or both electrodes to 0V, setting the bulk region of the data transistor to 0V, then ramping up the control voltage of the selected row from 0V to the predefined maximum control voltage V_{cmax} and the erase voltage of the selected row from 0V to the predefined maximum erase voltage Vₑₘₐₓ and holding these voltages for a predefined program time T_{prog}, then ramping down the control voltage from V_{cmax} to 0V and the erase voltage from Vₑₘₐₓ to 0V;
for each NVM cell selected not to be programmed in the selected array row, setting the source electrode of the data transistor to an inhibiting voltage V_{N} and the drain electrode of the data transistor to floating, or the drain electrode of the data transistor to the inhibiting voltage V_{N} and the source electrode of the data transistor to floating, or both electrodes to the inhibiting voltage V_{N}, then ramping up the control voltage of the selected row from 0V to V_{cmax} and the erase voltage from 0V to Vₑₘₐₓ and holding these voltage for the predefined program time T_{prog}, then ramping down the control voltage of the selected row from V_{cmax} to 0V and the erase voltage of the selected row from Vₑₘₐₓ to 0V;
for each NVM cell in an array row selected not to be programmed, setting the control voltage and the erase voltage to 0V, setting the source electrode of the data transistor to 0V or the inhibiting voltage V_{N}, or the drain electrode of the data transistor to 0V or the inhibiting voltage V_{N}; and returning all electrodes having the inhibiting voltage V_{N} to 0V.

8. The method of claim 7, wherein the predefined maximum control voltage V_{cmax} and the predefined maximum erase voltage Vₑₘₐₓ are both approximately 10V, and the predefined program time T_{prog} is approximately 20-50 milliseconds.

9. The method of claim 7, wherein the predefined maximum control voltage V_{cmax} and the predefined maximum erase voltage Vₑₘₐₓ are both approximately 16V, and the predefined program time T_{prog} is approximately 20-50 milliseconds.
